(19) United States
(12) Patent Application Publication
(10) Pub. No.: US 2004/0108568 A1
(43) Pub. Date: Jun. 10, 2004

(54) Superjunction device with added charge at top of pylons to increase ruggedness

(75) Inventor: Zhijun Qu, Torrance, CA (US)

Correspondence Address: OSTROLENK FABER GERB & SOFFEN, 1180 AVENUE OF THE AMERICAS, NEW YORK, NY, 100368403

(73) Assignee: International Rectifier Corporation

(21) Appl. No.: 10/680,898

(22) Filed: Oct. 8, 2003

Related U.S. Application Data
(60) Provisional application No. 60/417,212, filed on Oct. 8, 2002.

(51) Int. Cl. H01L 29/00

(52) U.S. Cl. 257/500

(57) ABSTRACT

The P type pylons in a superjunction device have an increased concentration at their top to modify charge balance, such that the top of the P regions are not fully depleted during blocking voltage operation, while the remainder of the P type pylons are in charge balance with the surrounding N body region. Avalanche current can then be diverted to the central portion of the P body (for N-channel device) channel region at the top of the pylon and away from the R_{b}′ under the source to increase ruggedness (turn on of the parasitic bipolar transistor due to avalanche current flow through R_{b}′) with very little sacrifice of breakdown voltage due to the increased concentration at the top of the pylons.

### RELATED APPLICATION

The present application is based on and claims benefit of U.S. Provisional Application Ser. No. 60/417,212, filed Oct. 8, 2002, entitled SUPERJUNCTION DEVICE WITH ADDED CHARGE AT TOP OF P PYLONS TO INCREASE RUGGEDNESS, to which a claim of priority is made.

### FIELD OF THE INVENTION

This invention relates to superjunction semiconductor devices and more specifically to the improvement of the ruggedness of such devices without substantially reducing the breakdown voltage of the device.

### BACKGROUND OF THE INVENTION

Superjunction devices are well known in which a plurality of spaced, parallel columns or pylons of one conductivity type extend though a portion or all of the thickness of a wafer of the other conductivity type. The pylons are P type for an N channel device, which is the example to be used herein. The pylons are then capped at their tops with a MOSgated structure which, when turned on, permits vertical current flow through the N body of the wafer. The total charge of the pylons is matched to that of the surrounding N body so that, in reverse bias, the P pylons and the N body fully deplete to block voltage across the thickness of the wafer.

It is known that avalanche current may flow in such devices under reverse bias. This avalanche current flows into the channel region and under the source regions of the MOSgated structures (the R_{b}¹ region of the device) and then to the source metal. If the horizontal portion of the avalanche current, hence, the voltage drop across the source—P body junction, is high enough, it can turn on the parasitic transistor in the MOS structure.

The horizontal portion of the avalanche current can be reduced by increasing the charge in the P pylons and overbalancing the P regions (no charge balance), thus making the device less susceptible to avalanche current turn-on. However, the increased pylon concentration reduces breakdown voltage since the P pylons are not fully depleted during reverse bias.

Thus, the design trade-off between device ruggedness (avalanche energy) and breakdown voltage is complicated.

In other words, to achieve both high breakdown voltage and high avalanche energy is a critical technique in the design of superjunction type of devices. When a superjunction device works with a perfect charge balance condition, it can support high reverse bias voltage. However, the large amount of the horizontal avalanche current through the R_{b}¹ will easily trigger the bipolar structure in the MOSFET device. On the other hand, when the device works with a higher, and unbalanced p-charge in the pylons, avalanche energy is usually high, but with a low breakdown voltage.

### BRIEF DESCRIPTION OF THE INVENTION

In accordance with the invention, only a small portion at the top of each pylon has an increased charge and thus is charge-unbalanced relative to its surrounding oppositely charged region.

A device according to the invention produces a favorable trade-off of breakdown voltage and avalanche energy. When only the top of the pylon receives a higher dose implant relative to its lower portion, the device can still withstand a high breakdown voltage. When the device is avalanched, the avalanche current is uniform at the lower portion of the device and starts to converge toward each pylon when it flows close to the top of the device. This keeps the avalanche current away from the R_{b}¹ region so that the device can hold a much higher avalanche energy.

In the preferred embodiment, 25% of the top portion of each pylon has an increased charge, and the remainder of each pylon has a balanced charge relative to its surrounding region. Also, preferably, the charge increase at the top of each pylon is about 15 to 20% greater than that of the remainder of its body. As a result, the preferred embodiment exhibits a favorable combination of breakdown voltage and avalanche energy. It should be noted that the values stated herein may be modified to obtain the desired tradeoff between the various characteristics of the device such as its ruggedness and its breakdown voltage rating.

### BRIEF DESCRIPTION OF THE DRAWINGS

FIG. 1 is a cross-section of a super unction wafer which includes the features of the invention.

FIG. 2 is a cross-section of FIG. 1 taken across section line 2-2 in FIG. 1.

FIG. 3 schematically illustrates the operation of the invention for a single pylon of FIGS. 1 and 2.

### DETAILED DESCRIPTION OF THE PREFERRED EMBODIMENT

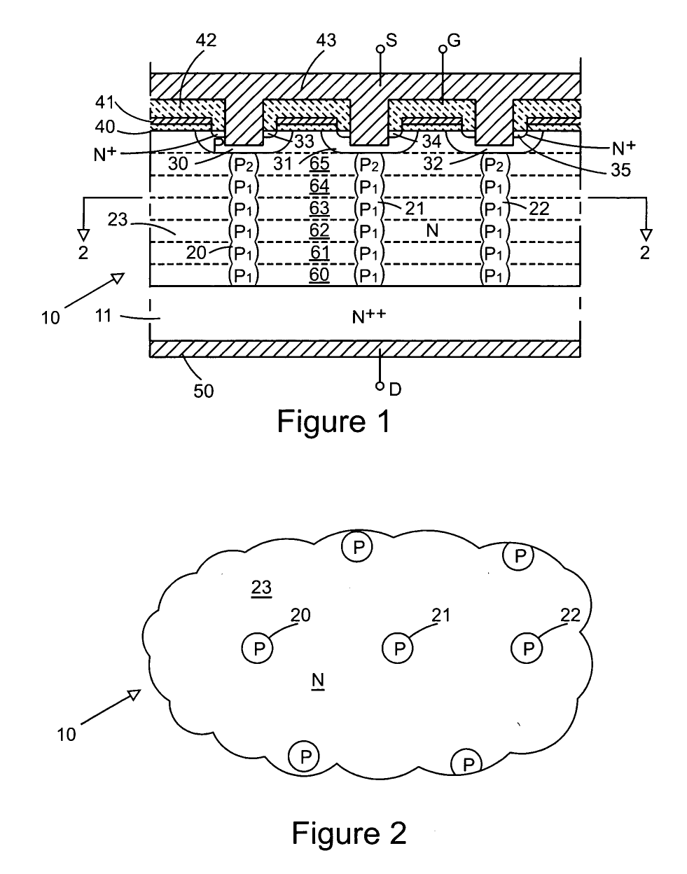

FIGS. 1 and 2 show a small portion of a superjunction MOSFET device of well-known construction which is modified in accordance with the invention as will be described.

The device is formed in a silicon wafer 10 (the term wafer is used interchangeably with chip or die) which has a main substrate portion 11, shown as highly doped (N⁺⁺) silicon. (FIGS. 1 and 2 show an N channel device. All conductivity types can be reversed to produce a P channel device.)

The superjunction concept includes the use of a plurality of spaced P type “pylons” 20, 21, 22 which extend vertically upward toward the upper surface of wafer 10. Conventionally, these pylons have a P concentration such that their total charge equals the total charge in the surrounding N type body 23 (usually an epitaxially deposited layer) of silicon above the substrate 11. In this way, during reverse bias, the P type pylons and N type body fully deplete to block voltage. However, the N type concentration in region 23 can be higher than that used for the conventional MOSFET so the device has a much lower on resistance when turned on.

A MOSgated structure is also provided in the usual manner, and is shown as P channel regions 30, 31, 32 which receive N⁺ source regions 33, 34, 35 respectively, which may be annular regions. The P⁻ regions in channels 30, 31 and 32 which are below the sources 40, 41 and 42 respectively are the R_{b}′ regions through which avalanche current can flow.

A gate oxide 40 overlies the invertible channel regions between the source regions and respective channel regions and a polysilicon gate electrode 41 overlies the gate oxide 40. An insulation layer 42 such as LTO overlies and insulates the polysilicon gate segments of gate 41 from an overlying source electrode 43. A drain contact 50 is connected to the bottom of wafer 10.

The pylons 20, 21 and 22 can be made in any desired way. One conventional process includes the sequential epitaxial deposition of N type layers 60 to 65, with aligned P type diffusions following the formation of each layer to form the final pylon. The number of layers and their thickness and concentrations are well-known. Typically, for a high voltage device, six layers will be used to get the needed length.

In accordance with the invention, the top portion of each of the pylons (and the diffusion in the top-most layer 65) has a greater concentration P₂ than that of the remaining portion of the column in which each diffusion has the concentration P₁. wherein P₁<P₂.

Note that the length of the pylon portion having an increased concentration is preferably less than about 25% (and is about 16% in the embodiment shown) of the full pylon length. Further, the concentration P₂ is preferably about 15 to 20% greater than P₁.

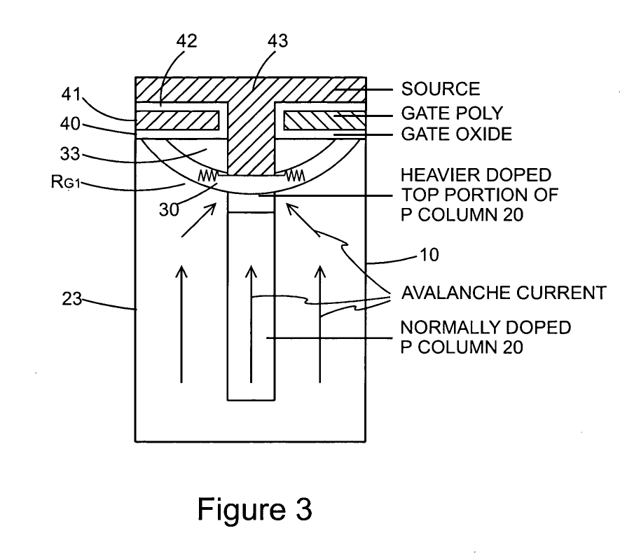

FIG. 3 shows the pylons 20 and shows the manner in which the heavier doped portion of the pylon or P column 20 improves the device operation.

Thus, achieving both high breakdown voltage and high avalanche energy is the aim of the critical design of superjunction type of device. When a superjunction works at perfect charge balance condition, it can support high reverse bias voltage between electrode 43 and 50 (FIG. 1). However, a large avalanche current through the R_{b}¹ will easily trigger the bipolar structure in the MOSFET device section. On the other hand, when the device works with a higher p-charge in the pylon, avalanche energy is usually high, but with a reduced breakdown voltage.

This invention improves the trade-off of breakdown voltage and avalanche energy. Thus, when only top of the p-column 20 receives a higher dose implant P₂ (than that of the lower portion of the p-column), the device still can withstand a relatively high breakdown voltage. When the device is avalanched, however, the avalanche current, as shown by arrows in FIG. 3, is uniform at the lower portion of the device but starts to converge toward the p-column close to top of the device. This keeps the avalanche current away from the R_{b}′ region under source 33 so that the device can handle a much higher avalanche energy.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. In a superjunction semiconductor device; a semiconductor body region of a first conductivity type and having parallel top and bottom surfaces; a plurality of spaced pylons of the other conductivity type extending through at least a portion of the thickness of said body region; a respective MOSgated structure including a source region disposed in a channel region which is positioned above and in contact with each of said pylons, the major length of said pylons extending from their ends which are closest to said bottom surface being in charge balance with the body region surrounding them; the remaining length of each of said pylons at the top thereof having a higher concentration than that of said major length whereby avalanche current is at least partly directed toward the center of the top of said pylon and away from the R_{b′} region in said channel and beneath said source.

2. The device of claim 1 wherein said charge in said remaining length is up to about 20% greater than that in said major length of said pylon.

3. The device of claim 1 wherein said remaining length of said pylons is less than about 25% of the length of said pylon.

4. The device of claim 2 wherein said remaining length of said pylons is less than about 25% of the length of said pylon.

5. A P type semiconductor pylon in an N type body for a superjunction device; said P type pylon having an increased concentration at its top end which is greater than and overbalances the concentration of the surrounding N type body; the remainder of the length of said pylon being in charge balance with the surrounding N type body.

6. The device of claim 5 wherein said charge in said remaining length is up to about 20% greater than that in said major length.

7. The device of claim 5 wherein said remaining length of said pylons is less than about 25% of the length of said pylon.

8. The device of claim 6 wherein said remaining length of said pylons is less than about 25% of the length of said pylon.

9. A superjunction device having improved avalanche capability; said device comprising a semiconductor wafer body of one conductivity type and having a major electrode on the bottom of said wafer; a plurality of identical and spaced pylons of the other conductivity type extending through at least a portion of the thickness of said wafer; at least the lower portions of said pylons being in charge balance with said wafer body; and a portion of the top of said pylons having a greater charge than that of said lower portions.

10. The device of claim 9 wherein the charge in said top of said pylons is about at least 15 to 20% greater than that of said lower portions.

11. The device of claim 9 wherein the length of said portion of said top is less than about 25% of the full length of said pylons.

12. The device of claim 10 wherein the length of said portion of said top is less than about 25% of the full length of said pylons.

13. The device of claim 9 which further includes MOSgated structures disposed at the top of each of said pylons; said MOSgated structure comprising a channel region of said opposite conductivity type and which extends across and overlaps its respective pylon; a respective source region of said one conductivity extending into each of each channel regions and defining R_{b′} regions in said channels and beneath said sources which are removed from the outer periphery of said pylon top; a gate structure extending across respective invertible channel regions between said source and channel regions at the top of said wafer; and a source electrode extending over the top of said wafer and in contact with each of said source and channel regions.

14. The device of claim 13 wherein the charge in said top of said pylons is about at least 15 to 20% greater than that of said lower portions.

15. The device of claim 13 wherein the length of said portion of said top is less than about 25% of the full length of said pylons.

16. The device of claim 14 wherein the length of said portion of said top is less than about 25% of the full length of said pylons.
